(19) United States
(12) Patent Application Publication
(10) Pub. No.: US 2025/0301909 A1
(43) Pub. Date: Sep. 25, 2025

(54) HIGH PERFORMANCE MOLECULAR THERMOELECTRIC DEVICES USING ORGANOMETALLIC CHAINS CAPABLE OF COHERENT NEAR-RESONANT TUNNELING AND MANUFACTURING METHOD THEREOF

(71) Applicant: KOREA UNIVERSITY RESEARCH AND BUSINESS FOUNDATION, Seoul (KR)

(72) Inventors: Hyo Jae YOON, Seoul (KR); Jiung JANG, Seoul (KR); Jeongwoo JO, Busan (KR)

(73) Assignee: KOREA UNIVERSITY RESEARCH AND BUSINESS FOUNDATION, Seoul (KR)

(21) Appl. No.: 19/041,143

(22) Filed: Jan. 30, 2025

(30) Foreign Application Priority Data
Jan. 30, 2024 (KR) 10-2024-0014031

(51) Int. Cl. H10N 10/856; H10N 10/01; H10N 10/82

(52) U.S. Cl. CPC H10N 10/856; H10N 10/01; H10N 10/82

(57) ABSTRACT

The present disclosure relates to a high performance molecular thermoelectric device using an organometallic molecular chain capable of coherent near-resonant tunneling, and relates to a method of forming an organometallic molecular chain capable of coherent near-resonant tunneling on an electrode surface using an electrochemical reduction grafting method, a thermoelectric assembly (molecular junction) using the same, a high performance molecular thermoelectric device and investigating thermoelectric properties.

### TECHNICAL FIELD

The present disclosure relates to a high performance molecular thermoelectric device using an organometallic molecular chain capable of coherent near-resonant tunneling.

### BACKGROUND ART

Thermoelectric devices based on a large-area molecular tunneling junction enable the development of nano-scale thermoelectric devices, and when a molecule is adsorbed on an electrode to form an electrode-molecule-electrode molecular junction, the energy level of the molecule has a certain level of linewidth. A Seebeck coefficient (S=−ΔV/ΔT) in a molecular tunneling junction represents a ratio of thermovoltage (ΔV) generation depending on a temperature difference (ΔT) between the two electrodes, and is determined by the slope of a molecular energy level at an electrode Fermi level (E_{F}) by the Mott formula. The slope of this molecular energy level becomes steeper as a gap (ΔE) between the molecular energy level and the electrode Fermi level is smaller, and as a result, a large Seebeck coefficient may be expected.

In a Simmons model (J=J₀e^{-βd}), a tunneling current (J) decreases exponentially as a molecular length increases (herein, J represents tunneling current, d represents thickness of tunneling barrier, J₀ represents theoretical tunneling current when tunneling barrier is 0, and β represents extinction coefficient of tunneling current (tunneling extinction coefficient). Due to the property of tunneling current decreasing exponentially, it is generally difficult to detect a tunneling current in a region of a few nm or larger. However, it has been reported that, when ΔE is extremely small, charge transport between electrodes may be extended to a region of up to about 15 nm by near-resonant tunneling.

As a method of reducing resistance for a long molecular chain by reducing a tunneling current (β), incoherent tunneling (or hopping) may be used in addition to inducing coherent tunneling (or tunneling) in a state of extremely small ΔE [Science 2008, 320, 1482-1486].

Herein, when charge transport by coherent tunneling is dominant in a state of small ΔE, a Seebeck coefficient increases as the molecular chain length increases, however, when incoherent tunneling is dominant, a Seebeck coefficient does not increase even when the molecular length increases.

A thermoelectric effect in a molecular tunneling junction using a simple molecule may not be expected to have high performance due to the low Seebeck coefficient level of <100 μV/K, and an organometallic unit-based organometallic molecular chain may be expected to have a high Seebeck coefficient since it is based on coherent near-resonant tunneling, however, there is a difficulty in molecular synthesis due to low solubility and complex structure.

### DETAILED DESCRIPTION OF THE INVENTION

### Problems to be Solved by the Invention

Accordingly, the present disclosure is directed to providing a high performance molecular thermoelectric device using a Ru(tpy)₂ (tpy means terpyridine)-based organometallic molecular chain capable of coherent near-resonant tunneling, the molecular chain formed on an electrode surface using an electrochemical reduction grafting method.

### Means for Solving the Problems

One embodiment of the present disclosure provides a thermoelectric assembly including: a metal substrate; and an organometallic molecular chain thin film bonding to the metal substrate and having thermoelectric properties.

According to one embodiment of the present disclosure, the organometallic molecular chain thin film may be a thin film in which an organometallic molecular unit represented by the following [Chemical Formula 1] forms a chain through a covalent bond, and the organometallic molecular chain bonds to the metal substrate through the covalent bond.

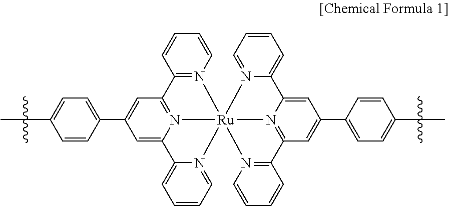

According to one embodiment of the present disclosure, the metal substrate may be atomic-level ultrathin template gold or silver (Au^{TS} or Ag^{TS}) made by template-stripping (TS).

According to one embodiment of the present disclosure, the metal substrate is a lower electrode, an upper electrode is provided opposite to the lower electrode, and the organometallic molecular chain thin film may be included between the lower electrode and the upper electrode. In addition, the upper electrode may be a liquid metal eutectic gallium-indium (EGaIn) alloy, and has a conductive thin gallium oxide (Ga₂O₃) thin film layer formed on the surface by a self-passivating reaction.

In addition, one embodiment of the present disclosure provides a method for manufacturing the thermoelectric assembly according to the present disclosure, the method including the following steps of:
(i) dissolving the following [Chemical Formula 2] having an amine (—NH₂) group in a solution including hydrochloric acid (HCl) and sodium nitrate (NaNO₃) to form a derivative having a diazonium (—N₂⁺) of the following [Chemical Formula 3];
(ii)) applying an external electric field to the solution to release the diazo (—N₂⁺) group and form a radical chemical species; and
(iii) forming a covalent bond between the radical chemical species and the metal substrate or an organometallic molecule adsorbed on the metal substrate to form a molecular chain on the metal substrate surface.

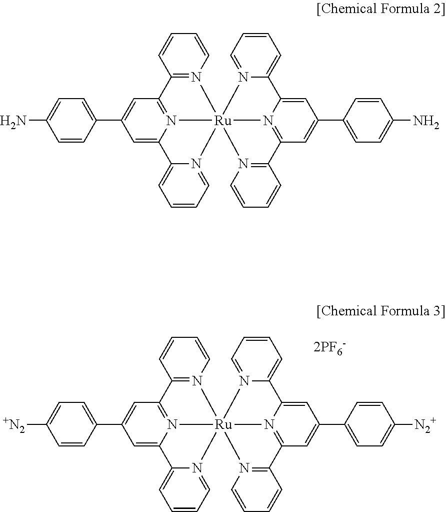

According to one embodiment of the present disclosure, a thickness of the molecular chain thin film may be controlled by adjusting a size of the applied external electric field and the number of electric field applications in the step (ii).

In addition, one embodiment of the present disclosure provides a molecular thermoelectric device including: an upper electrode; a lower electrode provided opposite to the upper electrode; and an organometallic molecular chain thin film formed on the lower electrode.

According to one embodiment of the present disclosure, the organometallic molecular chain thin film may be a thin film in which an organometallic molecular unit represented by the following [Chemical Formula 1] forms a chain through a covalent bond.

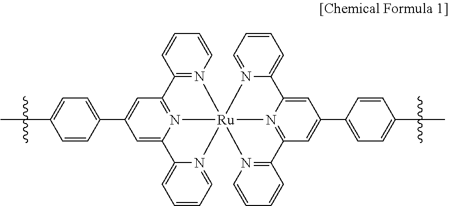

According to one embodiment of the present disclosure, the organometallic molecular chain bonds to the metal substrate through the covalent bond.

According to one embodiment of the present disclosure, the lower electrode may be atomic-level ultrathin template gold or silver (Au^{TS} or Ag^{TS}) made by template-stripping (TS).

According to one embodiment of the present disclosure, the upper electrode may be a liquid metal eutectic gallium-indium (EGaIn) alloy, and has a conductive thin gallium oxide (Ga₂O₃) thin film layer formed on the surface by a self-passivating reaction.

According to one embodiment of the present disclosure, the organometallic molecular chain thin film may have a thickness of 1 nm to 20 nm, and a Seebeck coefficient value increases as the thickness increases.

### Effects of the Invention

The present disclosure is capable of manufacturing an organometallic molecular chain (Ru(tpy)₂ molecular chain) thin film, which can achieve excellent thermoelectric properties by having a high Seebeck coefficient, with improved process efficiency compared to existing methods by using an electrochemical reduction grafting method, and is capable of controlling thermoelectric properties by adjusting a thickness of the thin film, and as a result, is capable of developing a high performance molecular thermoelectric device using the same.

In the present disclosure, it is identified that the Seebeck coefficient of the organometallic molecular chain linearly increases as the length of the molecule increases, which has experimental significance of clarifying that charge tunneling mechanism in the Ru(tpy)₂ chain is coherent tunneling in a state of small ΔE.

The molecular thermoelectric device according to the present disclosure has a Seebeck coefficient of up to 1027 μV/K, which corresponds to the highest value in literature, in a result of molecular thermoelectricity measurement using a liquid metal eutectic gallium-indium (EGaIn) alloy.

The present disclosure experimentally identifies that charge transfer mechanism in a molecular assembly is deeply related to a thermoelectric phenomenon, and this is expected to serve as a basis for establishing design rules for molecular thermoelectric devices, and developing thermoelectric devices with more superior performance in the future.

### BRIEF DESCRIPTION OF DRAWINGS

FIG. 1A is a diagram schematically illustrating a Ru(tpy)₂ molecular chain thin film according to one embodiment of the present disclosure. Au^{TS} is a gold substrate (Au^{TS}) made with an ultrathin template, and EGaIn/Ga₂O₃ is a eutectic Ga—In metal having a conductive thin gallium oxide (Ga₂O₃) thin film layer formed on the surface by a self-passivating reaction.

FIGS. 2B to 2D are representative high-resolution X-ray photoelectron spectra of a Ru(tpy)₂ molecular chain thin film according to one embodiment of the present disclosure having a thickness of 6.3 nm±0.3 nm for C1s, Ru3d, Ru3p and N1s regions (open circle symbols are raw data).

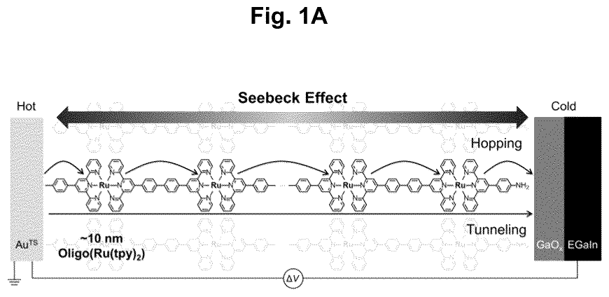

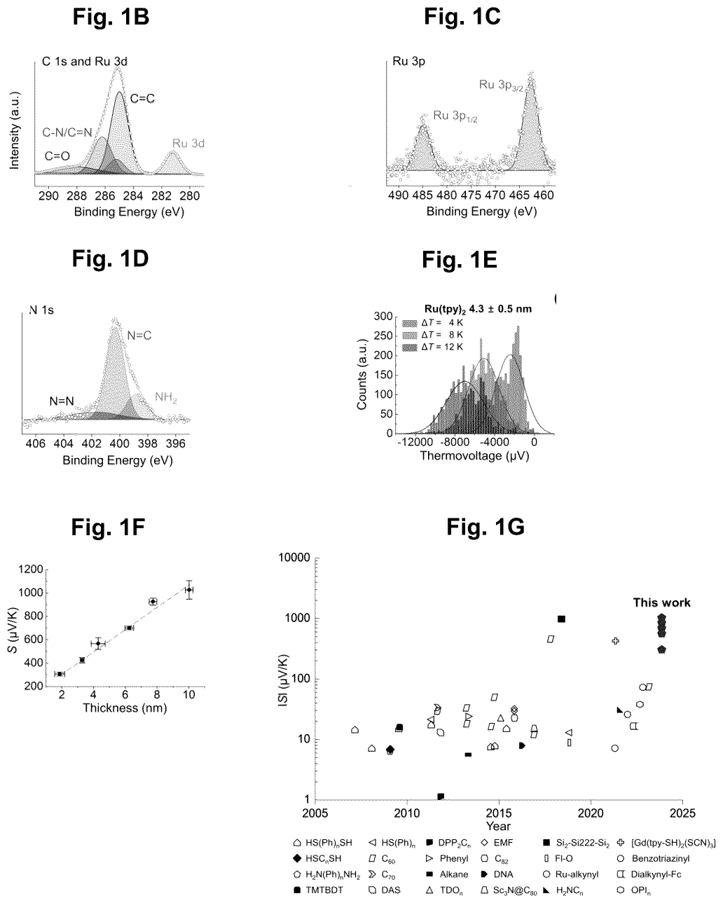

FIG. 1E is a representative thermovoltage histogram of a Ru(tpy)₂ molecular chain thin film according to one embodiment of the present disclosure having a thickness of 4.3 nm±0.5 nm obtained by EGaIn bonding technique.

FIG. 1F is a plot of a Seebeck coefficient (S, μV/K) depending on the thickness of the Au^{TS}/Ru(tpy)₂ molecular chain thin film.

FIG. 1G compares the S value of the Ru(tpy)₂ molecular chain thin film according to one embodiment of the present disclosure with values of other molecular thin films reported in existing literature, and open symbols and closed symbols respectively represent conjugated molecules and non-conjugated molecules.

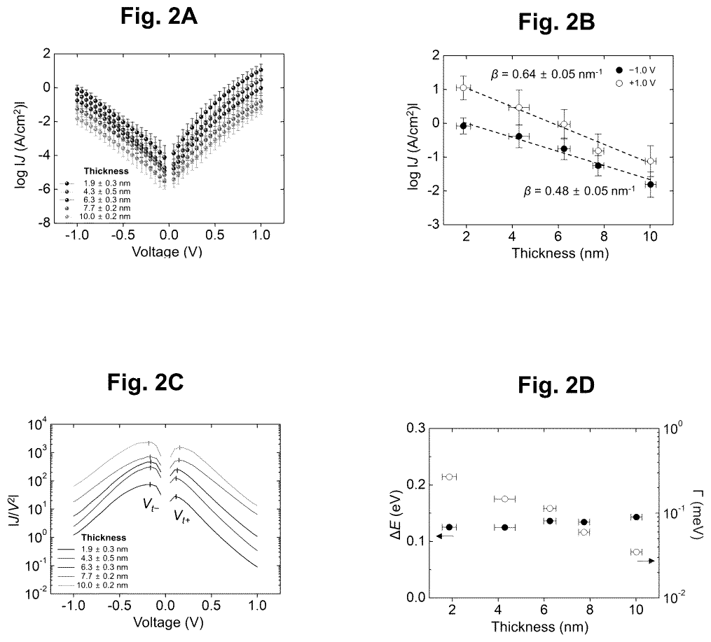

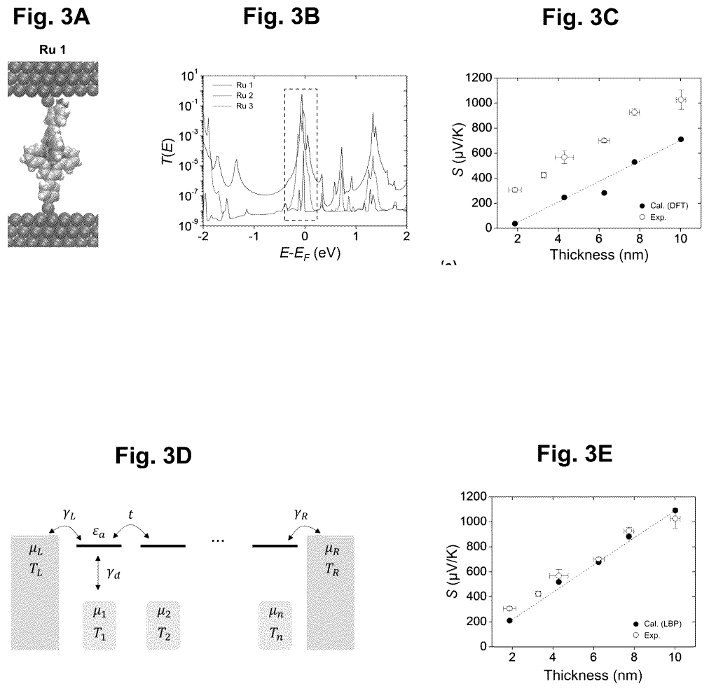

FIG. 2A is a Log₁₀|J|−V curve of the Ru(tpy)₂ molecular chain thin film according to one embodiment of the present disclosure.

FIG. 2B is a graph showing length dependence of Log₁₀|J| at ±1.0 V.

FIG. 2C is a plot of |J/V²| for V used to determine a transition voltage (V_{t±}). The solid vertical line represents the transition voltage (V_{t±}).

FIG. 2D is a plot of energy offset (ΔE, eV) and energy level broadening (Γ, meV) estimated in transition voltage spectroscopy (TVS) combined with a single-level model (SLM).

FIG. 3A shows a molecular junction structure according to the present disclosure including the Ru(tpy)₂ molecular chain thin film used in density function theory (DFT) calculation.

FIG. 3B shows a transfer function derived from the density function theory (DFT) calculation. The Fermi level is shifted to reproduce a β value, and sharp peaks around the Fermi level (indicated by a red dotted box) show a high S value.

FIG. 3C shows length dependence of S determined by the experiment and the DFT calculation, and the dotted line represents a linear regression of a trend theoretically predicted in S.

FIG. 3D is a diagram schematically describing a Landauer-Buttiker probe (LBP) technique, and herein, εₐ is site energy of the Ru(tpy)₂ unit, t represents transfer integral, γ_{(L,R)} represents binding energy for an electrode, γ_{d} represents binding energy of the Ru(tpy)₂ unit, and μᵢ and Tᵢ (i=L, R; 1, 2, 3, . . . , n) represent chemical potential and temperature of lead and each probe.

FIG. 3E is a graph showing length dependence of S determined by the experiment and the LBP technique, and the dotted line represents a linear regression of a trend theoretically predicted in S.

### BEST MODE FOR CARRYING OUT THE INVENTION

Hereinafter, the present disclosure will be described in more detail.

The present disclosure relates to a high performance molecular thermoelectric device using a Ru(tpy)₂ (tpy means terpyridine)-based organometallic molecular chain capable of coherent near-resonant tunneling, the molecular chain formed on an electrode surface using an electrochemical reduction grafting method.

In addition, the present disclosure relates to a method for manufacturing a Ru(tpy)₂ molecular chain having a thickness of a several to tens of nanometers using an electrochemical reduction grafting method.

In addition, the present disclosure relates to a method for improving a Seebeck coefficient of molecular junction using coherent near-resonant tunneling in the Ru(tpy)₂ molecular chain.

In addition, the present disclosure provides an analysis on tunneling mechanism of molecular junction using length dependence of a Seebeck coefficient of a molecular assembly (molecular junction).

In the Ru(tpy)₂ molecular chain thin film (FIG. 1) according to the present disclosure, the HOMO (highest occupied molecular orbital) level of the repeated unit is placed very close to the Fermi level of an electrode, and a significant tunneling current may be maintained up to a long length of 10 nm or greater.

This phenomenon is due to coherent tunneling with small ΔE, and a molecular junction having a high Seebeck coefficient may be manufactured by increasing the length of the Ru(tpy)₂ molecular chain according to the present disclosure (FIG. 1).

In addition, the present disclosure relates to a manufacturing method including the following characteristic steps based on an electrochemical reduction grafting method in order to increase the length of the Ru(tpy)₂ molecular chain, and to manufacture a thermoelectric assembly:
(i) dissolving the following [Chemical Formula 2] having an amine (—NH₂) group in a solution including hydrochloric acid (HCl) and sodium nitrate (NaNO₃) to form a derivative having a diazonium (—N₂⁺) of the following [Chemical Formula 3];
(ii) applying an external electric field to the solution to release the diazo (—N₂⁺) group and form a radical chemical species; and
(iii) forming a covalent bond between the radical chemical species and the metal substrate or an organometallic molecule adsorbed on the metal substrate to form a molecular chain on the metal substrate surface.

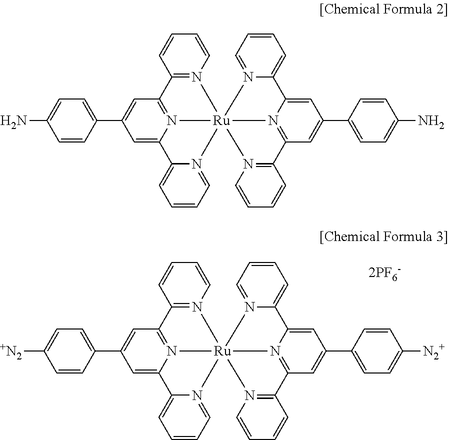

According to one embodiment of the present disclosure, an aqueous solution of 1 M HCl, 0.1 M Ru(II) (tpy)₂ and 1.5 M NaNO₂ is used as an electrolyte under a condition of 4° C. or lower in order to perform the electrochemical reduction grafting method, and herein, a reference electrode is Ag/AgCl and a counter electrode is Pt wire.

According to one embodiment of the present disclosure, a thickness of the molecular chain thin film may be controlled by adjusting a size of the applied external electric field and the number of electric field applications in the step (ii).

Hereinafter, the present disclosure will be described in more detail with reference to specific experimental examples and analysis examples.

In the field of molecular electronic devices, long-range charge transfer through electrode-molecule-electrode tunneling junction is generally facilitated by two mechanisms. One is hopping resulting from thermal activation of electrons generally occurring in a weak bonding region between the molecule and the electrode, and the other is coherent resonant tunneling occurring in a strong bonding region. Experiments widely used to define transport properties include investigation on current temperature and length dependence. However, temperature dependence and critical length dependence of charge transfer are generally observed in the two mechanisms, and it is difficult to distinguish these.

Coherent resonant tunneling occurs when an energy level of molecular orbitals resonates with the Fermi level of an electrode. Considering that a tunneling attenuation coefficient (β, nm−1), which is a parameter that represents length dependence of tunneling current in a molecular junction, is proportional to a square of energy level offset in the Simmons model, coherent resonant tunneling may facilitate efficient charge transfer in a molecular junction. Coherent resonant tunneling generally represents low β (0.01 nm⁻¹ to 0.40 nm⁻¹) in a quite long molecular wire of up to 5 nm to 15 nm.

Almost all molecular structures facilitating coherent resonant tunneling rely on π-extended components such as porphyrin and diketopyrrolopyrrole, and produce a small energy offset between the Fermi level and an accessible molecular orbital energy level. Some structures include redox-active metals to create an “intermediate” energy state buried between ligand-induced potential barriers. Such resonance between the accessible molecular orbital and the Fermi level needs to reduce the offset between the energy levels in order to induce coherent resonant tunneling, and therefore, is effective when an external voltage (0.2 V to 1.0 V) is applied to the molecular junction.

A Seebeck effect in a molecular junction is evaluated by a thermovoltage and an open circuit voltage generated by a temperature gradient applied to the junction. Studies on the Seebeck effect provides unique information that is hardly accessible by existing electrical measurements such as polarity of dominant charge carrier and shape of energy barrier. The Seebeck coefficient may show distinct length dependence between coherent tunneling and thermally activated hopping transport even when conductivity that varies with length is similar.

Accordingly, the inventors according to the present disclosure have identified a Seebeck effect in the Ru(tpy)₂ molecular chain thin film that facilitates long-range transfer through coherent resonant tunneling as follows, and have completed the present disclosure.

The thin film was manufactured using an electrochemical reduction grafting method, the properties were identified using X-ray photoelectron spectroscopy (XPS) (FIGS. 1B to 1D), and the thermovoltage (ΔV, μV) was sufficiently measured statistically at various temperature differences (ΔT, K; FIG. 1E) using eutectic Ga—In (EGaIn). It was identified that, as the thickness of the thin film increased, the Seebeck coefficient (S, μV/K) linearly increased with a dramatic increase rate of 95.6 μV/(K·nm) (FIG. 1F). The S value was in a range of 307 μV/K to 1027 μV/K, and the Seebeck coefficient far exceeded values known in existing molecular thermoelectric devices (FIG. 1G). Density function theory (DFT) calculation and transition voltage spectroscopy (TVS) indicate the presence of molecular orbital resonance near the Fermi level, and this explains the high Seebeck coefficient. This clearly shows that such a trend of increase in the S value identified in the present disclosure is due to resonant tunneling transport.

Regarding the theoretical model of the present disclosure, assuming that a single molecule level rules charge transfer through molecular junction and the molecule energetically bonds to the electrode, the charge transfer through the junction is generally described by the following Lorenz-shaped transfer function (T(E)).

$$T ( E ) = \frac{{Γ}^{2}}{{( E - {E}_{M O} )}^{2} + {Γ}^{2}}$$

T(E) varies depending on the position of accessible molecular orbital (E_{MO}) for the Fermi level (E_{F}) and the extension of E_{MO}(Γ). The Seebeck coefficient S of the junction is determined by the slope of ln(T(E)) at E_{F} according to the Mott formula.

$${S \approx \frac{{π}^{2} {k}_{B}^{2} T}{3 e} \frac{\partial ln T ( E )}{\partial E} \vert}_{E = {E}_{F}}$$

Herein, k_{B} is a Boltzmann constant, T is a junction temperature, and e is an electron charge. The sign of S value is polarity of a dominant charge carrier, with the positive sign indicating that hole tunneling dominates thermal power and the highest occupied molecular orbital (HOMO) energy level is near E_{F}, and the negative sign indicating electron tunneling through the lowest unoccupied molecular orbital (LUMO) level.

Whereas a structurally simple organic molecule having a large HCMO-LUMO gap generally follows resonant tunneling and represents an appropriate Seebeck coefficient (30 μV/K or less) (refer to FIG. 1G), an organometallic compound inherently having a narrower HOMO-LUMO gap may provide a high S value. Accordingly, the inventors of the present disclosure have completed the present disclosure, focusing on a Ru(tpy)₂ unit-based organometallic molecular chain. Theoretically, such an organometallic compound is known to produce multiple resonance transfer peaks that overlap each other and shift to the E_{F} direction, thereby inducing a high S of up to about 150 μV/K.

The mechanism of forming the Ru(tpy)₂ molecular chain thin film according to one embodiment of the present disclosure may be described as follows.

The amino group reacts with nitrosonium ions generated through the reaction between HCl and NaNO₂ to form the corresponding diazonium salt, and when an external electric field is applied thereto, the diazonium salt is decomposed to release N₂ gas, and radicals remain. These radicals then bond to gold atoms exposed on the surface of the metal substrate, or react with the organic ligand portion of the Ru(tpy)₂ already adsorbed through a covalent bond.

In the present disclosure, the Ru(tpy)₂ molecular chain thin film is embodied as an active component having thermoelectric properties, and rectification of tunneling current, photoelectric effect, efficient long-range tunneling and optical switching are obtained.

More specifically, the method for manufacturing a thermoelectric assembly including the Ru(tpy)₂ molecular chain thin film according to the present disclosure includes the following steps of:
(i) dissolving the following [Chemical Formula 2] having an amine (—NH₂) group in a solution including hydrochloric acid (HCl) and sodium nitrate (NaNO₃) to form a derivative having a diazonium (—N₂+) of the following [Chemical Formula 3];

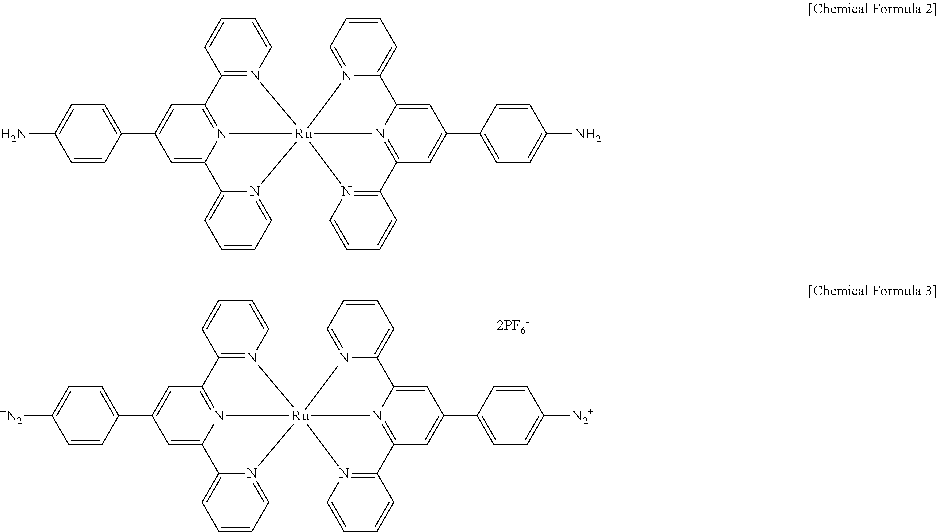

(ii) applying an external electric field to the solution to release the diazo (—N₂+) group and form a radical chemical species; and
(iii) forming a covalent bond between the radical chemical species and the metal substrate or an organometallic molecule adsorbed on the metal substrate to form a molecular chain on the metal substrate surface.

In addition, in one embodiment of the present disclosure, the Ru(tpy)₂ molecular chain thin film is formed on flat template strip gold (Au^{TS}), and herein, the thickness of the film may be controlled by adjusting the magnitude of the applied external voltage and the number of applications.

In a specific embodiment of the present disclosure, the thickness of the Ru(tpy)₂ molecular chain thin film increases as the voltage magnitude and/or the number of voltage applications increase, and the thickness reaches up to 1.9±0.3 nm, 3.3±0.1 nm, 4.3±0.5 nm, 6.3±0.3 nm, 7.7±0.2 nm and 10.0±0.2 nm.

In addition, as a result of characterizing the Ru(tpy)₂ molecular chain thin film according to one embodiment of the present disclosure using X-ray photoelectron spectroscopy (XPS), the C is peak is separated into three peaks at 284.9 eV, 286.1 eV and 288.4 eV corresponding to C—C or C═C in the molecular backbone and C—N in the amino or pyridine group (FIG. 1B). The presence of Ru atoms is identified by two doublet peaks at 281.2 and 285.2 eV in the case of Ru 3d_{5/2} and 3d_{3/2}, respectively, and 462.7 and 485.0 eV in the case of Ru 3p_{3/2} and 3p_{1/2}, respectively (FIGS. 1B and 1C). The N is signal is separated into three peaks at 400.2 eV, 401.3 eV and 398.8 eV representing C═N in the pyridine ligand, N═N in the diazo group and C—N in the amino group (FIG. 1D). In addition, traces of the diazo group are observed, and this indicates that the radical species is efficiently formed under the external electric field application. The atomic percentages of carbon, nitrogen and ruthenium derived from the integral of deconvoluted peaks are identified to be almost identical to the theoretical values.

Thermoelectric properties of the assembly including the Ru(tpy)₂ molecular chain thin film according to one embodiment of the present disclosure are as follows.

The thermoelectric assembly was manufactured and a thermovoltage was measured thereon in the present disclosure, and, in order to produce a temperature gradient (ΔT, K) in the entire assembly, the Au^{TS} lower electrode was heated with a Peltier element, and numerous data were collected in other assemblies in order to obtain an average value of ΔV.

FIG. 1E shows a representative histogram of ΔV, with each histogram roughly showing normal distribution, and average and standard deviation values are extracted by fitting a Gaussian curve to the histogram. The Seebeck coefficient (S, μV/K) is determined by the slope of linear regression in the plot of ΔV versus ΔT. In order to extract the S value of the thermoelectric assembly according to the present disclosure, thermal power contribution of the electrode is considered according to a procedure previously reported, and FIG. 1F shows length dependence (thickness dependence) of the Ru(tpy)₂ molecular chain thin film.

The model proposed in the art in order to describe the length dependence of S in the tunneling junction is as follows.

$$S = {S}_{C} + d \cdot {β}^{S}$$

Herein, d is the width of energy barrier produced through molecular junction, and S_{c} represents a Seebeck coefficient for a virtual junction with a length of 0 (d=0). This equation indicates that thermal power of the junction is linearly correlated with d with the slope of β^{S} (μV/(K·nm)).

The S value of the Ru(tpy)₂ molecular chain thin film according to one embodiment of the present disclosure linearly increases from 307 μV/K to 1027 μV/K as the thickness of the thin film increases from 1.9 nm to 10.0 nm, and the β^{S} value is 98.5 μV/(K·nm).

A typical S range of a structurally simple organic molecule is about 30 μV/K (FIG. 1G). Elongation of the conjugated backbone through imine condensation between arylamine and aldehyde is up to about 6.7 nm, and the S value is 38.0 μV/K. Considering this typical S value in the field of molecular thermoelectric devices, the Ru(tpy)₂ molecular chain thin film according to one embodiment of the present disclosure has a noticeably large S value, which is two to three orders of magnitude higher than the typical range. In addition, the S value is 11 times higher than the value of a Ru-alkynyl complex (73 μV/K) having a similar length (about 4 nm) (FIG. 1G).

Tunneling attenuation coefficient (β) and transition voltage spectroscopy (TVS) are as follows.

Length dependence of a tunneling current is generally described by a simplified Simons model.

$$J = {J}_{C} {e}^{- d β}$$

Herein, J represents current density (A/cm²), d represents an energy barrier width, J_{c} represents current density flowing through a virtual junction where a molecular length is 0 (d=0 nm) but the junction is not shorted, and β (nm⁻¹) is a tunneling attenuation coefficient.

In the present disclosure, β for the Ru(tpy)₂ molecular chain thin film according to one embodiment of the present disclosure having a different thickness is determined using EGaIn bonding technique.

FIG. 2A is a log_{10|}J|−V curve of the thin film, and the β values at +1.0 V and −1.0 V are 0.64±0.05 nm⁻¹ and 0.48±0.05 nm⁻¹, respectively, (FIG. 2B), which are consistent with previously reported values. These values are one order of magnitude smaller than the values of self-assembled monolayers (SAM) of alkanethiolate (7.5 nm⁻¹) and oligophenylenethiolate (2.9 nm⁻¹), which represent tunneling, and these 3 values remain constant over the entire thickness range (1.9 nm to 10.0 nm) according to the embodiments of the present disclosure.

ΔE and Γ of the assembly according to the present disclosure were estimated by adopting transition voltage spectroscopy (TVS) to correlate with the high S value and using a single-level model (SLM). The transition voltage (V_{t±}) (FIG. 2C) determined in the V versus |J/V²| plot where the |J/V²| value is maximized is closely related to ΔE and Γ.

The ΔE value estimated in the Ru(tpy)₂ molecular chain thin film according to the present disclosure is noticeably smaller than the value of a short molecule previously reported, and the value falls in the range of 0.125 eV to 0.150 eV (FIG. 2D and the following [Table 1]).

A general ΔE value of oligophenylenethiol molecular junction is from 0.49 eV to 1.12 eV, and the value of Ru-alkynyl complex determined by the DFT calculation is about from 0.136 eV to 0.322 eV. According to the Mott formula, the small ΔE value of the Ru(tpy)₂ molecular chain thin film according to the present disclosure explains the high S value. The small Γ value means a sharp transmission peak, and although the ΔE value remains constant over the entire thickness range of the thin film according to examples, Γ undergoes a first degree decrease as the film thickness increases (FIG. 2D and the following [Table 1]). Such a noticeable decrease in Γ implies that sharpness of the transmission function depending on the thin film thickness dominates the trend of increase in S.

The density function theory (DFT) may be calculated as follows.

In the present disclosure, the electronic structure of the Ru(tpy)₂ molecular chain according to the present disclosure was investigated by adopting a nonequilibrium green function method combined with DFT (NEGF-DFT) (FIG. 3A). In addition, in order to reflect interfacial properties of an actual system, an asymmetric anchor having a direct Au-carbon contact on one side of the molecular chain and a van der Waals NH₂/Au interface on the other side was adopted.

Sharp transmission peaks are mostly observed at the Fermi level (FIG. 3B), and this means a possibility of being close to resonant tunneling, and the high value of S, a significantly sharp slope of ln(T(E)) at E_{F}, may be understood. This is consistent with the results of TVS analysis, and shows a significantly small ΔE value. Since DFT is not that accurate in predicting an energy level, the Fermi level is adjusted to +0.10 eV in order to reproduce experimentally observed β. A high Seebeck coefficient may be identified in NEGF-DFT, and a trend of increasing up to 37 μV/K to 710 μV/K (FIG. 3C) is shown depending on the molecular chain length.

Quantitative simulations on the absolute value of S are difficult since S is proportional to the slope of transmission function on a natural logarithmic scale, and especially when the transmission peak is very sharp due to weak bonding, the slope is significantly affected by the theory level and structural details of the molecular junction.

The sharp transmission peak near the Fermi level may be explained by the following two reasons. First, separation of π-electrons in the molecule may be considered. Bonding generally increases when a delocalized π-electron cloud is in direct contact with an electrode. Since two π-plans are orthogonally aligned at the Ru center of the Ru(tpy)₂ molecule according to the present disclosure, the transmission peak of the Ru(tpy)₂ molecular chain is narrower than transmission peaks of other π-continuous structures such as porphyrin wires. Second, a phenyl spacer is present between the Ru(tpy)₂ centers and between the Ru(tpy)₂ and the electrode. The calculated transmission function is much narrower than that of Ru(tpy)₂s directly connected to each other.

A Landauer-Buttiker Probe (LBP)-based simulation is as follows.

DFT calculations have several shortcomings in quantitatively predicting a Seebeck coefficient for an organometallic molecular chain such as in the present disclosure, and tend to have inaccurate energy level alignment and overestimate bond strength. Therefore, a Landauer-Buttiker Probe (LBP) technique was used to perform the calculation.

The LBP technique is based on the Landauer formula, but includes depolarization of electron tunneling through a bond between a hopping site, which is considered as a metal unit, and a reservoir (FIG. 3D). FIG. 3E shows a simulated trend of S as a function of the thin film thickness. The LBP model favorably reproduces not only a linearly increasing trend of S but also the absolute value. The LBP simulation-based extrapolation method beyond the range of experimental results implies that the incremental trend of S continues up to 18 nm as the thickness of the thin film increases. In the LBP simulation, the S value decreases to a constant value (795 μV/K) at the thin film thickness of greater than 18 nm, and this means that the Seebeck effect enters a region dominated by thermal hopping.

The trend of increase in S depending on the thickness of the Ru(tpy)₂ molecular chain thin film according to one embodiment of the present disclosure is a clear characteristic of coherent near-resonant tunneling, and is consistent with the TVS analysis (FIG. 2D and the following [Table 1]).

In addition, the site energy (εₐ) of the Ru(tpy)₂ unit closely matches the Fermi level in the LBP simulation in the present disclosure, showing that the trend of S experimentally observed is well reproduced.

It is identified that γ_{d} is 0.01 when εₐ is −0.08 eV, and considering that γ_{d} of a conjugated molecular system transited by thermal hopping is 0.185 eV in the pure tunneling (that is, resonant tunneling released) of 3.4 nm according to a previous report, the γ_{d} value according to the present disclosure is significantly small compared to this literature value, and this means that coherent near-resonant tunneling close to resonance occurs in the long molecular chain.

In addition, S, which is independent of the length of the thick film, may be described by the following hopping critical formula.

$${S}_{H} \sim \frac{{k}_{B}}{e} \frac{4 {π}^{2}}{3} \frac{{k}_{B} T}{Δ E}$$

The Ru(tpy)₂ molecular chain thin film according to the present disclosure maintains a high S value due to the inherent critical energy offset.

A transport mechanism in a nano-scale molecular device, that is, coherent tunneling or hopping conduction, is an issue essential for rational design of the molecular device, and length dependence and temperature dependence of conductivity are useful properties for distinguishing the mechanism. However, this has a problem of being not conclusive when having small energy offset and frontier orbital bonding.

Experimental and theoretical studies on a length-dependent Seebeck coefficient as in the present disclosure clarifies the transport mechanism, and a linear increase in the length-dependent Seebeck coefficient indicates that the transport mechanism is coherent near-resonant tunneling. The small energy offset of HOMO is a necessary condition for the low β value accompanying the coherent tunneling, and is supported by TVS analysis and DFT calculation.

A high Seebeck coefficient is derived from the small energy offset of HOMO and the sharp transmission peaks. The Seebeck coefficient may further increase depending on the length, as predicted in the model calculation, and this is due to the fact that the transport mechanism is coherent tunneling. The high Seebeck coefficient may be maintained even in a hopping conduction region of greater than 20 nm. These results demonstrate that a highly efficient molecular thermoelectric device may be developed based on a metal composite molecule facilitating long-range charge transport.

TABLE 1

| Thickness (nm) | Vₜ₊ (V) | Vₜ₋ (V) | ΔE (eV) | Γ (meV) |
|---|---|---|---|---|
| 1.9 ± 0.3 | 0.123 | −0.174 | 0.125 | 0.269 |
| 4.3 ± 0.5 | 0.128 | −0.164 | 0.125 | 0.147 |
| 6.3 ± 0.3 | 0.143 | −0.174 | 0.136 | 0.114 |
| 7.7 ± 0.2 | 0.143 | −0.169 | 0.133 | 0.060 |
| 10.0 ± 0.2 | 0.153 | −0.179 | 0.150 | 0.035 |

[Table 1] shows parameters derived from the transition voltage spectroscopy (TVS) combined with the single-level model SLM).

As described above, thermoelectric properties were able to be identified after manufacturing the Ru(tpy)₂ molecular chain thin film capable of long-range transport in the present disclosure. Through the present disclosure, it may be clearly identified that the high S value and the trend of linear increase in S depending on the thin film thickness dominate the transport by coherent near-resonant tunneling rather than thermal hopping.

In addition, the experiment on the length dependence of S according to the present disclosure may provide clear insight into the transport mechanism that is difficult to access with traditional electrical measurements. The energy state alignment near the Fermi level is closely related to the rate of charge transfer and energy loss at the molecule-substrate interface, thereby having a broader meaning.

The present disclosure may be industrially utilized in various fields including heterogeneous catalysts, solar cells, spectroscopy and the like as well as molecular thermoelectric devices. Particularly, utilization of thermoelectricity may be expected in nano-scale devices.

1. A thermoelectric assembly comprising:
a metal substrate; and
an organometallic molecular chain thin film bonding to the metal substrate and having thermoelectric properties,
wherein the organometallic molecular chain thin film is a thin film in which an organometallic molecular unit represented by the following [Chemical Formula 1] forms a chain through a covalent bond, and the organometallic molecular chain bonds to the metal substrate through the covalent bond:

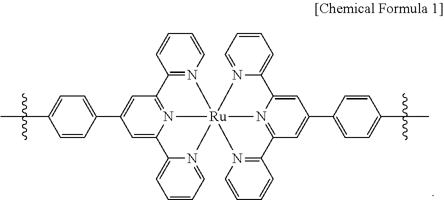

2. The thermoelectric assembly of claim 1, wherein the metal substrate is atomic-level ultrathin template gold or silver (Au^{TS} or Ag^{TS}) made by template-stripping (TS).

3. The thermoelectric assembly of claim 1, wherein the metal substrate is a lower electrode, an upper electrode is provided opposite to the lower electrode, and the organometallic molecular chain thin film is included between the lower electrode and the upper electrode, and the upper electrode is a liquid metal eutectic gallium-indium (EGaIn) alloy and has a conductive thin gallium oxide (Ga₂O₃) thin film layer formed on the surface by a self-passivating reaction.

4. A method for manufacturing the thermoelectric assembly of claim 1, the method comprising the following steps of:
(i) dissolving the following [Chemical Formula 2] having an amine (—NH₂) group in a solution including hydrochloric acid (HCl) and sodium nitrate (NaNO₃) to form a derivative having a diazonium (—N₂⁺) of the following [Chemical Formula 3];
(ii)) applying an external electric field to the solution to release the diazo (—N₂⁺) group and form a radical chemical species; and
(iii) forming a covalent bond between the radical chemical species and the metal substrate or an organometallic molecule adsorbed on the metal substrate to form a molecular chain on the metal substrate surface,

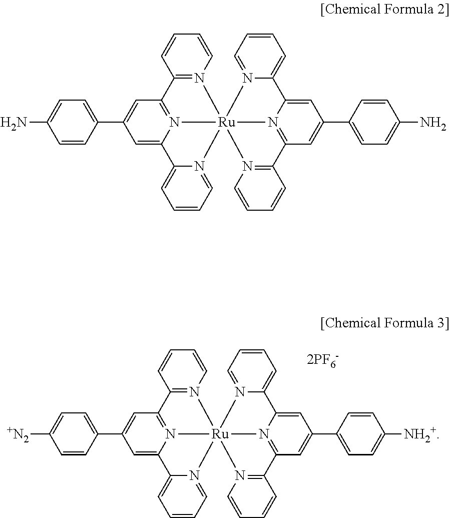

5. The method of claim 4, wherein a thickness of the molecular chain thin film is controlled by adjusting a size of the applied external electric field and the number of electric field applications in the step (ii).

6. A molecular thermoelectric device comprising:
an upper electrode;
a lower electrode provided opposite to the upper electrode; and
an organometallic molecular chain thin film formed on the lower electrode,
wherein the organometallic molecular chain thin film is a thin film in which an organometallic molecular unit represented by the following [Chemical Formula 1] forms a chain through a covalent bond, and the organometallic molecular chain bonds to the metal substrate through the covalent bond:

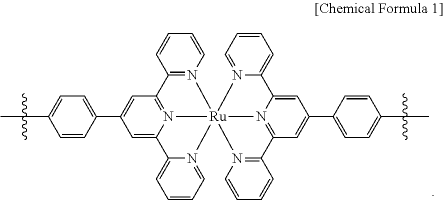

7. The molecular thermoelectric device of claim 6, wherein the lower electrode is atomic-level ultrathin template gold or silver (Au^{TS} or Ag^{TS}) made by template-stripping (TS).

8. The molecular thermoelectric device of claim 6, wherein the upper electrode is a liquid metal eutectic gallium-indium (EGaIn) alloy, and has a conductive thin gallium oxide (Ga₂O₃) thin film layer formed on the surface by a self-passivating reaction.

9. The molecular thermoelectric device of claim 6, wherein the organometallic molecular chain thin film has a thickness of 1 nm to 32 nm, and a Seebeck coefficient value increases as the thickness increases.
